(19) United States
(12) Patent Application Publication
(10) Pub. No.: US 2008/0211537 A1
(43) Pub. Date: Sep. 4, 2008

(54) Open drain output circuit

(75) Inventor: Kazutoshi Tsuda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/073,135

(22) Filed: Feb. 29, 2008

(30) Foreign Application Priority Data
Mar. 2, 2007 (JP) 53033/2007

(51) Int. Cl. H03K 17/16; H03K 19/003

(52) U.S. Cl. 326/33

(57) ABSTRACT

The transition time of an output is sometimes changed by a certain supply voltage connected to an output terminal of an output circuit. An output circuit to address this problem includes: a level detection circuit which detects a pull-up supply voltage applied to an output terminal OUT; and an open drain buffer circuit which can switch its driving ability on the basis of the detection result of the level detection circuit. Even if the output circuit is connected to a circuit whose supply voltage is different, it is made possible to produce an output while stabilizing the transition time of the output.

### BACKGROUND OF THE INVENTION

1. Field of the Invention

The present invention relates to an open drain output circuit, and particularly relates to an open drain output circuit of a case where there exist a plurality of power supply systems of a circuit to which the open drain output circuit is connected.

2. Description of the Related Art

An open drain buffer is used as an output buffer circuit of a semiconductor integrated circuit such as an I²C buffer. A non-patent literature, “THE I²C-BUS SPECIFICATION VERSION 2.1, JANUARY 2000, p. 8, Philips Semiconductors (NXP Semiconductors)” shows an open drain buffer taking an example of such an I²C-bus. FIG. 9 shows a schematic circuit diagram of an open drain buffer shown in the above-mentioned non-patent literature. As shown in FIG. 9, an output of an open drain buffer DOUT 1 and an input circuit DIN 2 of a circuit that comes next are connected to one output terminal OUT 71 in the I²C-bus. The output terminal OUT 71, which is connected to the output of the open drain buffer DOUT 1, is connected to a pull-up power supply VDD via an external resistor Rp.

Incidentally, the supply voltage (the IO supply voltage) used for an input/output circuit for the above-mentioned open drain buffer and the like has decreased to 1.8 V from 5 V through 3.3 V, and 2.5 V for the purposes of achieving higher integration and lower power consumption in recent years. In addition, such an input/output circuit has individually been designed in accordance with each IO supply voltage. Furthermore, when connecting input/output circuits whose IO supply voltages are different, a level shifter circuit is inserted between buffers in the I²C buffer, for example (see p. 43 in “THE I²C-BUS SPECIFICATION VERSION 2.1, JANUARY 2000, p. 8, Philips Semiconductors (NXP Semiconductors)”).

### SUMMARY OF THE INVENTION

However, when an output terminal of an open drain buffer designed for a circuit which operates with a power supply of 1.8 V is connected to an input circuit of a circuit which operates with a power supply of 3.3 V without inserting a level shifter circuit as described above, it is difficult to obtain preferable input/output characteristics between the two circuits.

In this respect, descriptions will be given of a case where an open drain buffer which operates with a power supply of 1.8 V is inputted in a circuit which operates with a power supply of 3.3 V, for example. In this case, it is possible to put an output terminal connected to the output of the open drain buffer to a level of 3.3 V (namely, the H level) by connecting the output terminal to the power supply of 3.3 V via an external pull-up resistor. However, the open drain buffer is designed to operate at a supply voltage of 1.8 V. Consequently, when the output terminal shifts from the H level to the L level, for example, the transition time is caused to increase.

Due to the change in transition time, the circuit may be caused to need so much time to shift the level that the circuit cannot meet the I²C specification, or may be caused to have a margin for speed that is extremely small. In other words, when a conventional open drain output circuit is connected to a circuit whose supply voltage is different, there has been a problem that the transition time of the output changes.

An open drain output circuit according to an aspect of the present invention includes: a level detection circuit which detects a pull-up supply voltage applied to an output terminal; and a buffer circuit which can switch its driving ability on the basis of a detection result of the level detection circuit.

According to the present invention, it is made possible to produce an output while stabilizing the transition time of the output, even if an open drain output circuit is connected to a circuit whose supply voltage is different.

### BRIEF DESCRIPTION OF THE DRAWINGS

FIG. 1 is a view showing an open drain output circuit of the present invention.

FIG. 2 is a schematic circuit diagram showing the details of an open drain output circuit of Embodiment 1.

FIG. 3 is a view showing voltage levels of Embodiment 1.

FIG. 4 is a schematic circuit diagram showing the details of an open drain output circuit of Embodiment 2.

FIG. 5 is a schematic circuit diagram showing the details of an open drain output circuit of Embodiment 3.

FIG. 6 is a schematic circuit diagram showing the details of an open drain output circuit of a modification example.

FIG. 7 is a schematic circuit diagram showing the details of an open drain output circuit of a modification example.

FIG. 8 a schematic circuit diagram showing the details of an open drain output circuit of a modification example.

FIG. 9 is a view showing a conventional output circuit.

### DESCRIPTION OF THE PREFERRED EMBODIMENTS

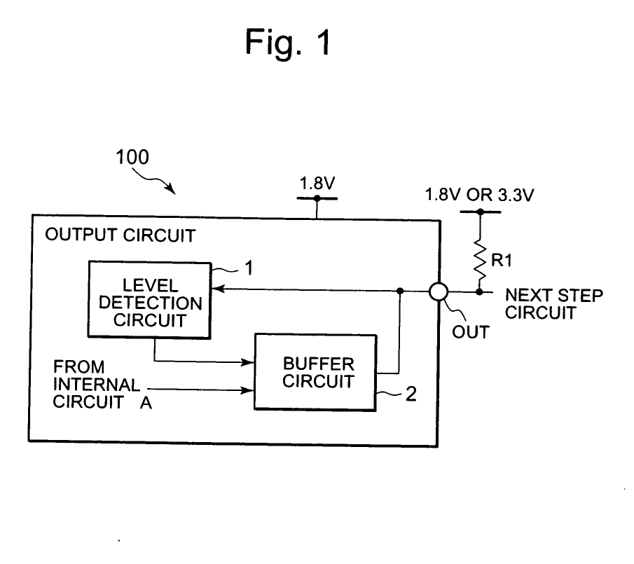

Detailed descriptions will hereinafter be given of embodiments of the present invention with reference to drawings. FIG. 1 is a schematic diagram showing an open drain output circuit 100 related to Embodiment 1 of the present invention. In the embodiment, the open drain output circuit 100 is placed in a circuit which operates at a first supply voltage (for example, 1.8 V), and also the open drain output circuit 100 itself operates at the first supply voltage of 1.8 V.

The open drain output circuit 100 of the embodiment includes a level detection circuit 1, and a buffer circuit 2. The level detection circuit 1 detects a voltage level of a pull-up power supply which applies voltage to an output terminal OUT at the time of starting the circuit, and outputs a level detection signal of the pull-up supply voltage applied to the output terminal OUT. The buffer circuit 2 is a circuit for outputting a signal at the H or L level on the basis of a signal A from an internal circuit. Note that the buffer circuit 2 changes its driving ability in accordance with the level detection signal from the level detection circuit 1. Descriptions will later be given of the change in the driving ability of the buffer circuit 2.

The output terminal OUT of the embodiment is connected to a second supply voltage (for example, a pull-up supply voltage) via a pull-up resistor R1 which is located outside the open drain output circuit 100. Here, the pull-up supply voltage is set to be a supply voltage of the next-step circuit which receives a signal outputted by the open drain output circuit 100, for example. The pull-up supply voltage may be a voltage of 1.8 V which is the same as that of the open drain output circuit 100, or may be a different voltage (for example, 3.3 V) from that of the open drain output circuit 100. However, descriptions will hereinafter be given of cases of being 1.8 V and 3.3 V as examples.

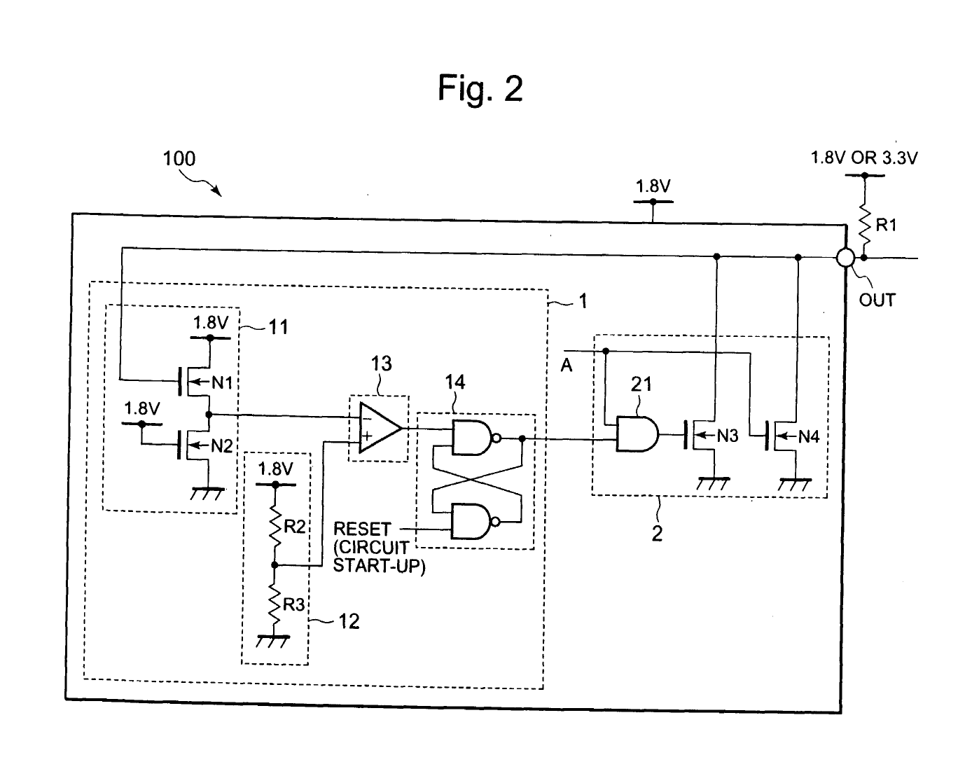

Detailed descriptions will be given of the level detection circuit 1 and the buffer circuit 2 by use of FIG. 2. The level detection circuit 1 of the embodiment has a level shifter 11, a reference voltage generator 12, a comparison unit 13, and a latch unit (a comparison result holder) 14. The level shifter 11 is a circuit which shifts and outputs the voltage of the output terminal OUT.

In the embodiment, the level shifter 11 is configured of two NMOS transistors N1 and N2, which are serially connected between the first supply voltage of 1.8 V and a grounding potential. A gate of the NMOS transistor N1, which is connected between the output of the level shifter 11 and the first supply voltage (1.8 V), is connected to the output terminal OUT of the open drain output circuit 100. Furthermore, a gate of the NMOS transistor N2, which is connected between the output of the level shifter 11 and the grounding potential, is provided with the first supply voltage being a fixed potential. In the embodiment, the level shifter 11 outputs voltages between 0 and 1.8 V in accordance with the level of a voltage of the output terminal OUT.

The reference voltage generator 12 is a circuit for generating a fixed reference voltage. In the embodiment, the reference voltage generator 12 is configured of resistors R2 and R3, which are serially connected between the first supply voltage and the grounding potential. The reference voltage generator 12 outputs a predetermined voltage on the basis of a ratio of the resistance values of the resistors R2 and R3.

The comparison unit 13 compares the voltage of the output terminal, which has been level-shifted by the level shifter 11, with the reference voltage outputted by the reference voltage generator 12, and then outputs the comparison result. In the embodiment, the comparison unit 13 is configured of a comparator using a differential amplifier. In the comparator in the embodiment, the output of the level shifter 11 on the basis of the voltage of the output terminal OUT is connected to an inverting input terminal. Additionally, the output of the reference voltage generator 12 is connected to a non-inverting input terminal. Accordingly, in the embodiment, the comparison unit 13 outputs a signal at the L level when the voltage of the output terminal OUT is higher than the output voltage of the reference voltage generator 12.

The latch unit 14 is a part to hold a signal which shows the comparison result by the comparison unit 13. Although detailed descriptions regarding the operation of the latch unit 14 will be given later, it is sufficient for the moment to summarize the role of the latch unit 14 in the embodiment such that the latch unit 14 holds the comparison result between the voltage of the output terminal OUT and the output voltage of the reference voltage generator 12 upon the start-up of the circuit. The latch unit 14 decides the driving ability of the buffer circuit 2 by holding the comparison result of the voltages immediately after the start-up. The latch unit 14 is configured of a reset-set flip-flop (RS-FF) in the embodiment. A start-up signal of the circuit is given to a reset terminal of the latch unit 14, and the latched value is reset whenever the circuit is started up. Note that although descriptions will hereinafter be given of an example on the basis of a case where the latch unit 14 is configured of a reset-set flip-flop (RS-FF), it is sufficient as long as the latch unit 14 is a resistor capable of holding the comparison result between the voltage of the output terminal OUT and the output voltage of the reference voltage generator 12 upon the start-up of the circuit.

The buffer circuit 2 in the embodiment is configured of an AND gate 21 and NMOS transistors N3 and N4, the transistors being connected between the output terminal OUT and the grounding potential. The NMOS transistors N3 and N4 are connected parallel with each other.

The AND gate 21 outputs a signal at the H or L level based on a signal A showing an output signal from the internal circuit and a logic signal from the latch unit 14. The output signal of the AND gate 21 is given to a gate of the NMOS transistor N3. The conduction status in the NMOS transistor N3 is controlled in accordance with the signal A from the internal circuit and the output of the AND gate 21.

The output signal A from the internal circuit is given to a gate of the NMOS transistor N4, and the conduction status is controlled in accordance with the output from the internal circuit.

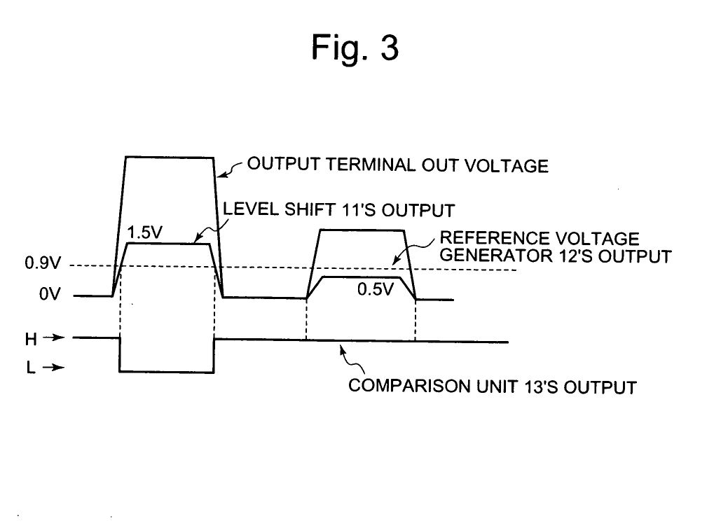

Taking an example of the circuit shown in FIG. 2, descriptions will be given of the operations of the embodiment of the present invention. Note that FIG. 3 is a view showing the applied voltage of the output terminal, the output voltage of the level shifter 11, and the output of the comparison unit 13 in the embodiment.

Here, descriptions will be given provided that the output terminal OUT of the open drain output circuit 100 is connected to a pull-up supply voltage of any one of 1.8 V and 3.3 V.

Firstly, after applying the pull-up supply voltage (either 1.8V or 3.3 V) to the OUT terminal while power is being supplied to a semiconductor chip having the open drain output circuit 100, the reset terminal of the latch unit 14 is set to be at the L level (“0”), and the signal A from the internal circuit connected to the open drain output circuit 100 is set to be at the H level (“1”).

Consequently, even if either pull-up supply voltage is applied, the voltage level of the OUT terminal is the L level. The output of the level shifter 11 is at the lower level than that of the output voltage of the reference voltage generator 12. Hence, the output of the comparison unit 13 turns to the H level (“1”), and the output of the latch unit 14 clears into the L level.

Afterwards, the reset is cancelled, that is, the level is put to the H level. Since the latch unit 14 is cleared in this status, the pull-up supply voltage at the lower level (here, 1.8 V) is selected.

Then, assume a case where the pull-up supply voltage which has been applied to the OUT terminal is at the higher level (3.3 V) when the signal A produces an output at the L level. In this case, the voltage level of the OUT terminal is equal to the pull-up supply voltage. Then, the output of the level shifter 11 is changed to the higher level than that of the output voltage of the reference voltage generator 12, and the output of the comparison unit 13 is changed to the L level. Consequently, the output of the latch unit 14 becomes the H level. In other words, a set value in which the applied pull-up supply voltage is set to be at the higher level (3.3 V) is taken into the latch unit 14.

On the other hand, assume a case where the pull-up supply voltage applied to the OUT terminal is at the lower level (1.8 V) . In this case, even if the signal A is at the L level and the voltage level of the OUT terminal is set to be the pull-up supply voltage, the level of the output of the level shifter 11 is not changed to the higher level than that of the output voltage of the reference voltage generator 12. Accordingly, the output of the comparison unit 13 stays at the H level. In other words, the latch unit 14 keeps the set value (L) which selects the lower level (1.8 V).

Furthermore, assume a case where the pull-up supply voltage is at the lower level (1.8 V) . In this case, even if the signal A produces an output at the H level (that is, OUT is at the L level) afterwards, the output of the level shifter 11 is at the lower level than that of the output voltage of the reference voltage generator 12 regardless of the pull-up supply voltage. Accordingly, the set value which selects the level taken into the latch unit 14 is not changed.

Next, descriptions will be given of the level shifter 11. In the level shifter 11, the NMOS transistor N2 operates as a current source. Since the voltage between the gate and source of N1 is decided to be equal to the drain current flowing in N2, the voltage outputted by the level shifter 11 is changed due to the voltage given to the gate of the NMOS transistor N1. For example, when L and W of N1 and N2 are equal, the voltage between the gate and source of N1 is equal to the voltage between the gate and source of N2. Hence, when the voltage of the output terminal OUT is 3.3 V, the output voltage of the level shifter 11 is 1.5 V.

The output voltage of the reference voltage generator 12 can be an arbitrary value, depending on the setting of the resistors R2 and R3. Here, the output voltage of the level shifter 11 exceeds the output voltage of the reference voltage generator 12 provided that R2 is equal to R3 and the voltage is 0.9 V. Consequently, the comparison unit 13 outputs a signal at the L level (see FIG. 3). The RS-FF of the latch unit 14 is set to the H level, and holds and outputs the H level. Since the latch unit 14 holds and outputs the H level, the AND gate 21 produces an output at the H or L level on the basis of the signal A outputted by the internal circuit.

If the next step circuit to which the open drain output circuit 100 is connected is a circuit which operates at a higher voltage than the supply voltage of the open drain output circuit 100, the open drain output circuit 100 of the embodiment operates as a circuit which drives the output signal by the NMOS transistors N3 and N4.

Consequently, in the embodiment, if the next step circuit to which the open drain output circuit 100 is connected is a circuit which operates at a higher voltage than the supply voltage of the open drain output circuit 100, the output signals are driven by two of the transistors N3 and N4. In this case, the buffer circuit 2 in the open drain output circuit 100 can operate as a circuit with a high driving ability.

In contrast, if the next step circuit to which the open drain output circuit 100 is connected is a circuit which operates at a lower voltage than that of the supply voltage of the open drain output circuit 100 (if the voltage of the output terminal OUT is 1.8 V), the output voltage of the level shifter 11 upon the start-up of the circuit is caused to be close to 0 V, since the open drain output circuit 100 operates in a manner that the voltage between the gate and source of N1 is equal to the voltage between the gate and source of N2. However, in reality, if 0 V is outputted, no current flows in N2. Consequently, a fixed voltage of approximately 0.5 V is generated between the drain and the source so that the current flows in N2. In this case, as described above, the output voltage of the reference voltage generator 12 exceeds the output voltage of the level shifter 11. Accordingly, the comparison unit 13 outputs a signal at the H level (see FIG. 3). The latch unit 14 holds a signal at the L level on the basis of the output from the comparison unit 13. Accordingly, the AND gate 21 outputs a signal at the L level regardless of the output signal A from the internal circuit. In this case, the NMOS transistor N3 does not contribute to the driving of the output signal, and the output signal is driven only by the NMOS transistor N4. Therefore, if the supply voltage of the next step circuit to which the open drain output circuit 100 is connected is 1.8 V, it is made possible to be the open drain output circuit 100 in which the output signal is driven only by the NMOS transistor N4, so that the driving ability is restrained.

In this manner, according to the embodiment of the present invention, it is made possible to change the driving ability of the buffer circuit 2 by the pull-up supply voltage detected by the level detection circuit 1 upon start-up. Accordingly, even if the supply voltage of the next-step circuit to which the open drain output circuit 100 is connected is changed, it is made possible to set the driving ability in accordance with the supply voltage in the open drain output circuit 100 by changing the driving ability of the buffer circuit 2. Hence, even if the supply voltage of the circuit which is connected after the open drain output circuit 100 is changed, the transition time of the output can be stabilized.

Note that, although the descriptions were given above taking the example that the open drain output circuit 100 operates with the supply voltage of 1.8 V and that the next step circuit operates at the supply voltage of 1.8 V or 3.3 V, the opposite case too is possible. For example, when the open drain output circuit 100 operates at the supply voltage of 3.3 V and the next step circuit operates at the supply voltage of 1.8V, it is possible to set the number of transistors to the best driving voltage in accordance with the next step circuit. Note that when the supply voltage of the circuit to which the open drain output circuit 100 is connected is lower than that of the open drain output circuit 100, or the like, the level shifter 11 shown in the embodiment is not necessarily essential. In other words, the open drain output circuit 100 of the present invention is designed, previously assuming a plurality of voltage levels of the pull-up power supply which can be connected to the output. Therefore, it is possible to judge that the voltage level of which pull-up supply voltage is applied on the basis of which is high or low between the pull-up supply voltage applied to the open drain output circuit 100 and the output voltage of the reference voltage generator 12. Thus, the output voltage level of the reference voltage generator 12 can be set to be a value between the pull-up voltage levels assumed to be applied (in other words, the pull-up supply voltage levels to be judged). For example, when the pull-up voltage level which has been assumed to be applied is any one of 1.8 V and 3.3 V, the output voltage of the reference voltage generator 12 may be at any level as long as the output voltage is a voltage between 1.8 V and 3.3 V. Hence, when the output voltage of the reference voltage generator 12 has a configuration in which a value between the pull-up voltage levels which has been assumed to be applied can be outputted, the level shifter 11 can be omitted. In this case, it is sufficient for the level detection circuit 1 to have a configuration which can detect the level of the output terminal OUT as described later.

### Embodiment 2

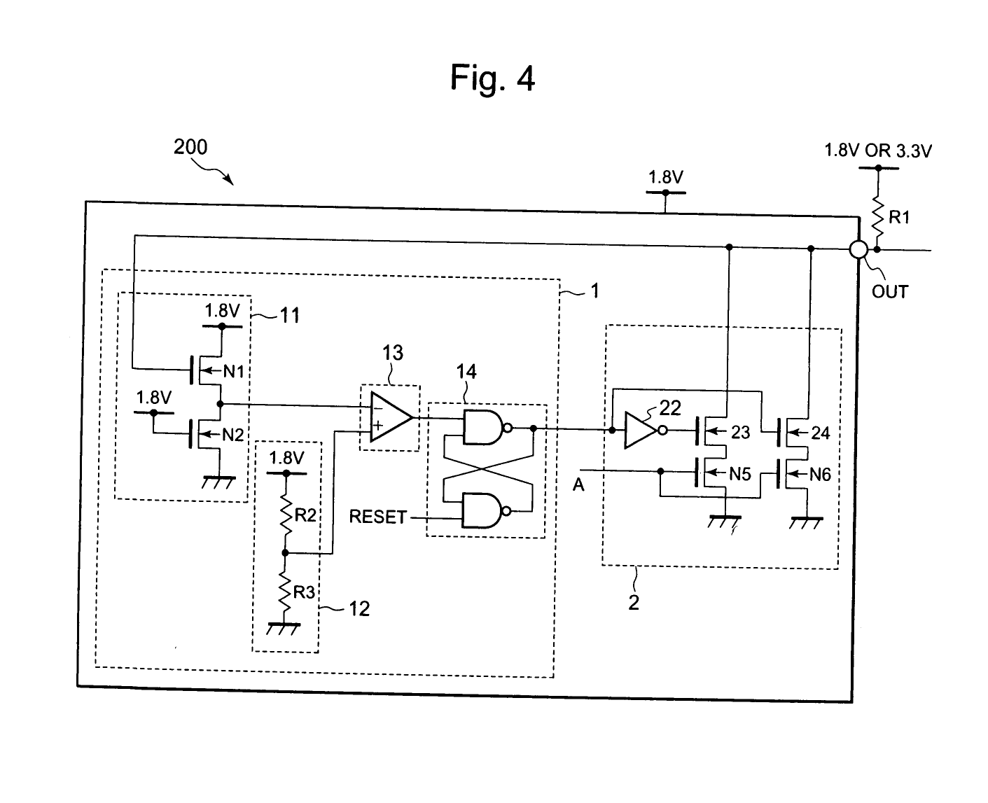

FIG. 4 is a schematic circuit diagram showing an open drain output circuit 200 of Embodiment 2 of the present invention. In FIG. 4, the same constituents as those in FIG. 2 are provided with the same symbols, and the detailed descriptions will be omitted. In the embodiment, the difference from Embodiment 1 is the configuration of the buffer circuit 2.

In the circuit shown in FIG. 4, the buffer circuit 2 is configured of an inverter 22, a switching elements 23 and 24, and NMOS transistors N5 and N6. The inverter 22 inverts and outputs the output of the above-mentioned latch circuit 14. The switching element 23 and the NMOS transistor N5 are serially connected between the output terminal OUT and the grounding potential. The switching element 24 and the NMOS transistor N6 are connected parallel with the switching element 23 and the NMOS transistor N5, and are serially connected between the output terminal OUT and the grounding potential. The conduction statuses of the switching elements 23 and 24 are controlled in accordance with the output of the latch unit 14. The signals A from the internal circuit are given to gates of the NMOS transistors N5 and N6. FIG. 4 shows an example of a circuit in which NMOS transistors are used as the switching elements 23 and 24. The NMOS transistors N5 and N6 are different in size, and are transistors whose current driving abilities are different.

In the circuit shown in FIG. 4, the operation is the same as the one shown in Embodiment 1 until the point where a signal in accordance with the supply voltage of the next step circuit is outputted by the level detection circuit 1. Here, given that the supply voltage of the next step circuit is higher than that of the open drain output circuit 200 and that the H level is outputted from the level detection circuit 1, the switching element 23 is OFF and the switching element 24 is ON. Consequently, when the supply voltage of the next step circuit is higher than that of the open drain output circuit 200, an output signal of the output terminal OUT is driven by use of the NMOS transistor N6. On the other hand, when the supply voltage of the next step circuit is the same as that of the open drain output circuit 200, the switching element 23 is ON and the switching element 24 is OFF. Consequently, the output signal of the output terminal OUT is driven by use of the NMOS transistor N5. Here, if the driving ability of the NMOS transistor N6 is set to be larger than that of the NMOS transistor N5, it is made possible to change the driving ability of the buffer circuit 2 in accordance with the supply voltage of the next step circuit as in Embodiment 1. In addition, at least six transistors are needed with the AND gate 21 in Embodiment 1, but the number of transistors to be added is four in this embodiment. Thus, it is made possible to reduce the number of parts.

### Embodiment 3

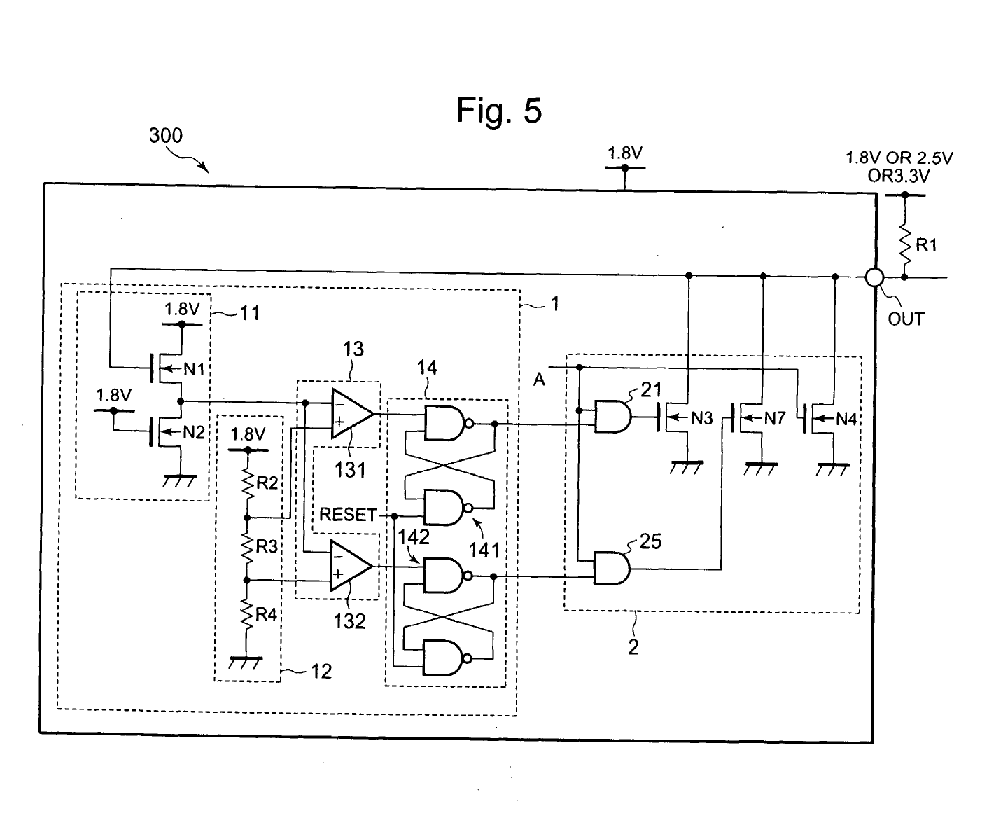

FIG. 5 is a schematic circuit diagram showing an open drain output circuit 300 of Embodiment 3 of the present invention. In FIG. 5, the same symbols are given to the same constituents as those in FIG. 2, and the detailed descriptions will be omitted. In the embodiment, a difference from Embodiment 1 is that multiple reference voltages are generated in the reference voltage generator 12. This configuration makes it possible to deal with a situation where the supply voltage of a circuit which is connected at a next step is divided into three levels, for example.

Accordingly, in the reference voltage generator 12 in the embodiment, three of the resistors R2, R3 and R4 are serially connected between the supply voltage and the grounding potential. Moreover, the comparison unit 13 has two comparators of first and second comparators 131 and 132. The latch unit 14 too has two RS-FFs 141 and 142 in order to hold the comparison results of the two comparators.

Furthermore, in the buffer circuit 2, provided are a second AND gate 25 and an NMOS transistor N7 which is connected between the output terminal OUT and the grounding potential.

A first reference voltage of a voltage dividing point (a node between R3 and R4) on the lower voltage side of the reference voltage generator 12 is connected to a non-inverting input terminal of the comparator 132, and a second reference voltage of a voltage dividing point (a node between R2 and R3) on the higher voltage side of the reference voltage generator 12 is connected to a non-inverting input terminal of the comparator 131.

The RS-FF 142 of the latch unit 14 receives input of the comparison result of the comparator 133, and holds the value. The RS-FF 141 holds the comparison result of the comparator 131. The value held by the RS-FF 142 is inputted into the second AND gate 25, and the value held by the RS-FF 141 is inputted into the first AND gate 21.

When the circuit is configured in this manner, both of the comparators 131 and 132 output signals at the L level when the voltage of the output terminal OUT is 3.3 V upon start-up, for example. Accordingly, an output signal is driven in the buffer circuit 2 by use of three transistors of the NMOS transistors N3, N4, and N7. When the voltage of the output terminal OUT is 2.5 V upon start-up, only the comparator 132 detects a signal at the L level, and an output signal is driven by use of the NMOS transistors N4 and N7. If the voltage of the output terminal OUT is 1.8 V upon start-up, both of the comparators 131 and 132 do not output signals at the L level (that is, the comparators output signals at the H level), and an output signal is driven by use of the NMOS transistor N4 alone.

In this manner, according to the embodiment, even if the supply voltages of the circuit connected to the output terminal OUT are various, it is possible to set the driving ability of the open drain output circuit 300 to the supply voltage. Note that when the supply voltages of the circuit connected to the output terminal OUT is considered to be more various, it is possible to deal with it by appropriately setting the reference voltage and the comparators to the number of voltage levels.

### MODIFICATION EXAMPLES

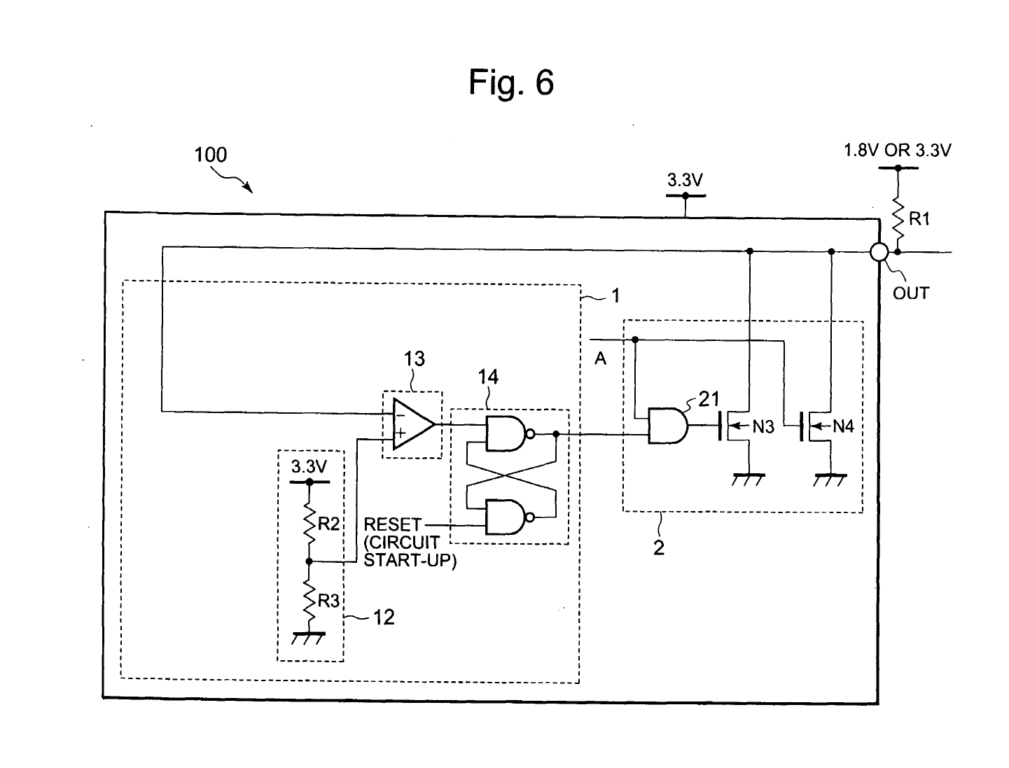

As described above, when the output voltage of the reference voltage generator 12 is configured to output a value between pull-up voltage levels which are assumed to be applied, the level shifter 11 can be omitted. FIG. 6 is a schematic diagram of a circuit of when the level shifter 11 is omitted in the open drain output circuit 100 described in the above Embodiment 1. Here, shown is a case where the open drain output circuit 100 of the present invention is connected to any one of the pull-up power supplies of 1.8 V and 3.3 V. The output voltages of the reference voltage generator 12 are configured to be supplied as voltage levels which are divided by R2 and R3 from the IO supply voltage (3.3 V) supplied to the open drain output circuit 100. Therefore, the reference voltage generator 12 can generate a value (desirably, an average value of 1.8 V and 3.3 V) between the pull-up voltage levels (1.8 V and 3.3 V), which are assumed to be applied, by use of the IO supply voltage (3.3 V), R2 and R3. In this case, as shown in FIG. 6, the output terminal OUT is connected directly to the inverting input terminal of the comparison unit 13. As long as the voltage resistance of a transistor which configures the comparison unit 13 can sufficiently deal with the open drain supply voltage connected to the output terminal OUT, it is possible to have such a configuration. With this, it is possible to reduce a circuit area since the level shifter 11 is unnecessary.

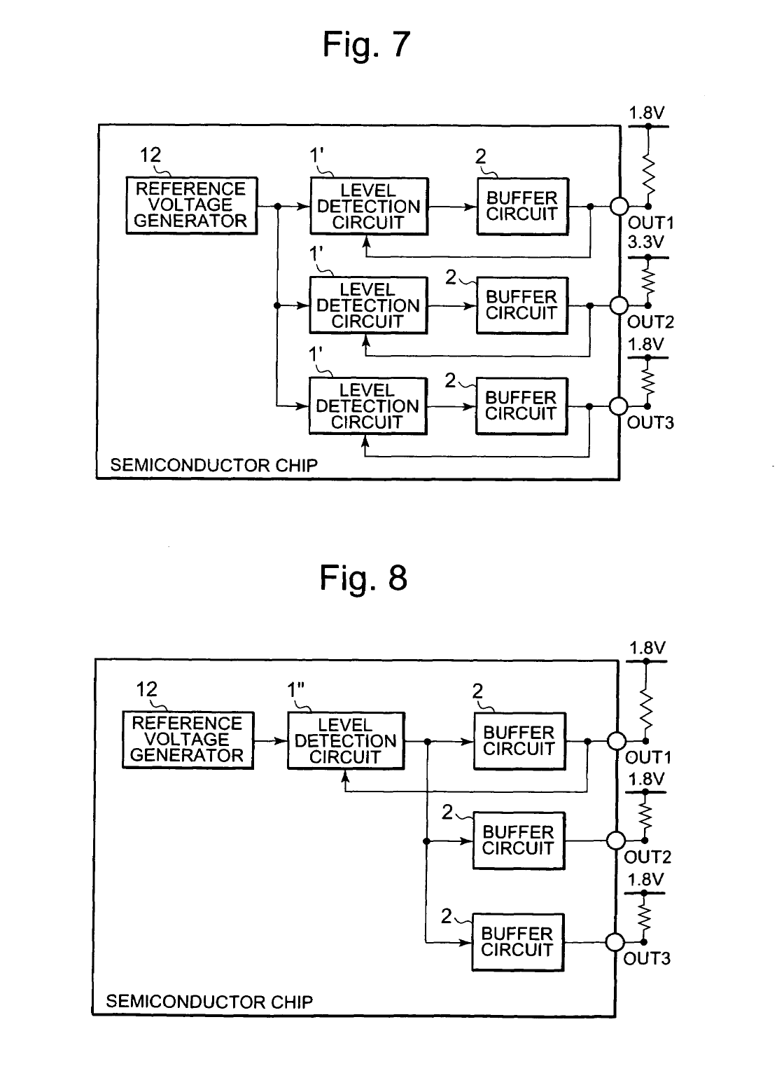

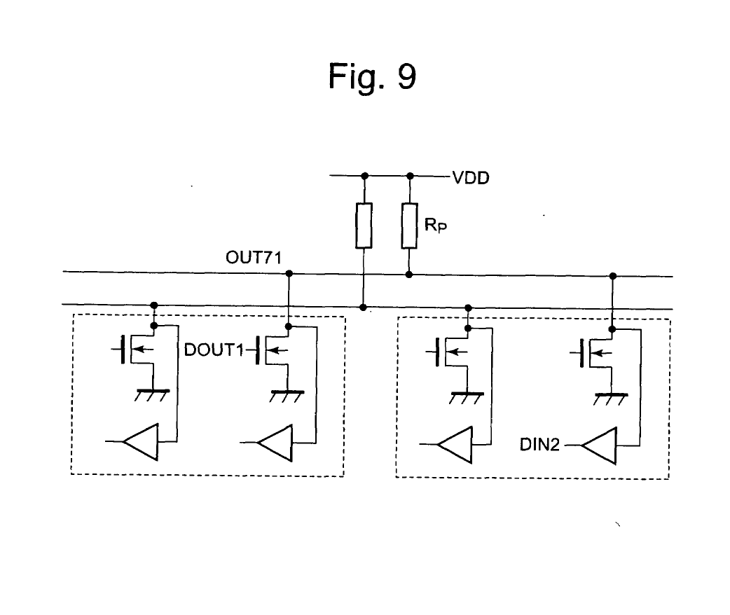

FIG. 7 is a schematic diagram showing another modification example of the embodiment. The schematic diagram shown in FIG. 7 is one for explaining a case of outputting a plurality of signals to a plurality of circuits. Each of level detection circuits 1′ is a level detection circuit which has only the level shifter 11, the comparison unit 13, and the latch unit 14 of the level detection circuit 1 shown in FIG. 2. The buffer circuit 2 may be a buffer circuit shown in any one of FIGS. 2 and 4. As shown in FIG. 7, when there are multiple outputs, it is made possible to provide the reference voltage generator 12 shown in FIG. 2 in common for the plurality of level detection circuits 1′.

With such a configuration that the reference voltage is commonly connected to the plurality of level detection circuits 1′ and buffer circuits 2, it is possible to provide a reference voltage for a plurality of open drain output circuits by providing one reference voltage generator 12 on a semiconductor chip, the semiconductor outputting multiple signals, for example. Furthermore, even if the supply voltages of the next step circuit to which output terminals OUT1, OUT2, and OUT3 are connected respectively are varied as illustrated in FIG. 7, it is possible to set the driving ability with each of the level detection circuits 1′ and generate output signals.

Note that in FIG. 7, the open drain buffers of the present invention of this application are designed to be connected to any one of pull-up power supplies of 1.8 V and 3.3 V, and that shown is a case where the pull-up power supply of 1.8 V is connected to the OUTs 1 and 3 and the pull-up power supply of 3.3 V is connected to the OUT 2, respectively. Although the level detection circuits 1′ are provided for the OUTs 1 to 3, respectively, it is configured that there is one reference voltage generator 12 since the output voltage of the reference voltage generator 12 for judgment can be used in common.

In addition, FIG. 8 shows a schematic diagram of still another modification example which is different from the one shown in FIG. 7. In the example shown in FIG. 7, the plurality of level detection circuits 1′ are provided for each of the multiple buffer circuits 2. In contrast, in the example shown in FIG. 8, the plurality of buffer circuits 2 are controlled by one level detection circuit 1″.

For example, in cases where a plurality of open drain output circuits configure a bus, and the like, these open drain output circuits are configured to be connected to the same pull-up power supply level. With regard to corresponding to the driving abilities of the open drain output circuits in accordance with the pull-up power supply level of the bus connection destination, it is possible to detect one of pull-up supply voltages of the open drain output circuits which configure the bus and to decide the driving abilities of all the open drain output circuits. In such a case, the open drain output circuit of the present invention of the application can be configured to be the one shown in FIG. 8. In FIG. 8, the plurality of open drain output circuits are connected to the pull-up supply voltage of 1.8V, but the pull-up supply voltage of 1.8 V is inputted from the OUT 1 to detect the level so that the driving abilities of all the open drain output circuits are changed.

The level detection circuit 1″ detects a pull-up voltage of one output terminal among the output terminals OUT 1 to OUT 3, and simultaneously controls the plurality of buffer circuits 2 connected to the same pull-up supply voltage in accordance with the detection result. The level detection circuit 1″ detects each voltage of the output terminals OUT 1 to OUT 3, and controls the plurality of buffer circuits 2 independently in accordance with the detection result.

As shown in FIGS. 2 and 6, for example, the specification has shown that the reference voltage generator 12 is configured so as to be supplied as voltage levels which are divided by R2 and R3 from the IO supply voltage (for example, 1.8 V and 3.3 V) supplied to the open drain output-circuit 100. However, it is possible for the reference voltage generator 12 to be configured of a regulator and the like in order to generate the reference voltage more accurately. The same is true to the reference voltage generators 12 in FIGS. 7 and 8.

Additionally, the voltage outputted by the reference voltage generator 12 may be a level capable of judging high or low of the pull-up voltage levels (1.8 V and 3.3 V) which are assumed to be applied, regardless of the presence or absence of the level shifter 11. When the level shifter 11 is omitted as in FIG. 6, the value may be one between the pull-up voltage levels (1.8 V and 3.3 V) which are assumed to be applied.

As described in detail on the basis of the embodiments, the driving ability of a buffer circuit in the open drain output circuit is decided by the pull-up supply voltage which is assumed to be applied to the output terminal in the present invention. Accordingly, even if there are multiple kinds of pull-up supply voltages connected to the open drain output circuit, the transition time of the output signal can be kept constant.

Although detailed descriptions have been given regarding the embodiments heretofore; various modifications are possible unless they do not depart from the spirit of the present invention. For example, it is also possible to combine the constituents of each embodiment and use the combination as an unillustrated circuit example. Moreover, the level shifter, the reference voltage generator, the latch unit, the buffer circuit, and the like are not limited to the circuit examples of the embodiments, and various modifications are possible as long as it is a circuit which can embody the operations described above in detail.

What is claimed is:

1. An open drain output circuit comprising:
a level detection circuit which detects a pull-up supply voltage applied to an output terminal; and
a buffer circuit with a driving ability that is switchable based on a detection result of the level detection circuit.

2. The open drain output circuit according to claim 1, wherein the buffer circuit is a buffer circuit including an open drain buffer.

3. The open drain output circuit according to claim 1, wherein the level detection circuit includes:
a comparison unit which compares a voltage applied to the output terminal with a reference voltage; and
a comparison result holder which holds a comparison result of the comparison unit.

4. The open drain output circuit according to claim 3, wherein the level detection circuit further includes a level shifter which level-shifts a voltage applied to the output terminal, and
the comparison unit compares an output voltage of the level shifter with the reference voltage.

5. The open drain output circuit according to claim 3, wherein the level detection circuit further includes a reference voltage generator which generates the reference voltage.

6. The open drain output circuit according to claim 3, wherein the comparison unit includes:
a first comparator which compares a voltage applied to the output terminal with a first reference voltage; and
a second comparator which compares a voltage applied to the output terminal with a second reference voltage.

7. The open drain output circuit according to claim 3, wherein the buffer circuit sets its driving ability on the basis of the comparison result held by the comparison result holder.

8. The open drain output circuit according to claim 3, wherein
the buffer circuit includes a plurality of output transistors, and
determination on which one of the output transistors is to generate output signals is made based on the comparison result held by the comparison result holder.

9. The open drain output circuit according to claim 3, wherein
the buffer circuit includes a plurality of output transistors, and
determination on the number of output transistors for generating output signals is made based on the comparison result held by the comparison result holder.
